(19) United States
(12) Patent Application Publication
(10) Pub. No.: US 2006/0256528 A1
(43) Pub. Date: Nov. 16, 2006

(54) Air Blown Chip Dissipation Device and Manufacturing Method Thereof

(76) Inventors: Ming-Hang Hwang, Taipei City (TW); Yu-Chiang Chen, Taipei City (TW); Chao-Yi Chen, Taipei City (TW); Ping-Feng Lee, Taipei County (TW); Hsin-Lung Kuo, Taipei City (TW); Bin-Wei Lee, Taipei City (TW); Wei-Chung Hsiao, Taipei City (TW)

Correspondence Address: LAW OFFICES OF LAI & ASSOCIATES, P.C., 5800 RANCHESTER, STE. 200, HOUSTON, TX, 77036, US

(21) Appl. No.: 11/307,809

(22) Filed: Feb. 23, 2006

(30) Foreign Application Priority Data
Mar. 2, 2005 (TW) 94106356

(51) Int. Cl. H05K 7/20

(52) U.S. Cl. 361/704; 361/695

(57) ABSTRACT

This invention discloses a manufacturing method and a device for an air blown chip heat dissipation. This heat dissipation device includes an air stream produce device, a plurality of heat sink fins, a heat dissipation slip and a heat pipe. The heat dissipation slip is often used in conducting the heat from a chip. The heat dissipation slip can be made of a special thermal conduction material, including the metal and a bracket structure of carbon element which have high thermal conductivity so as to improve the heat conduction efficiency. The corresponding manufacturing method for this thermal conduction material can be made with chemical vapor deposition, physical vapor deposition, electroplating or the other materials preparation method. The bracket structure of carbon element can coat on the metal surface and also can be mixed into the metal.

### FIELD OF THE INVENTION

The present invention relates to an air blown chip heat dissipation device and a manufacturing method and, more particularly, to the manufacturing method for a heat conduction material having a metal and a bracket structure of carbon element.

### BACKGROUND OF THE INVENTION

In recent years, the pace of high technology industry development is extremely fast, the development of electronic components is toward small volumes and high densities. The efficiency requirements for the aforesaid components also increase that generates much waste heat. The efficiency of the electronic components will be decreased and destroyed if the waste heat is unable to eliminate appropriately. Therefore, various heat conduction materials are provided to improve the efficiency of heat dissipation.

In the prior art, the material applying in the heat dissipation structure usually includes copper or aluminum to be the tendency of current heat dissipation technology. Traditionally, aluminum applying in the heat dissipation material is restricted to cause a bottleneck because of high temperature conduction is produced by the efficiency upgrade of central processors. Copper applying in the heat dissipation technology is then provided. However, copper has a higher specific gravity that has disadvantage to shape and the application is restricted. Although both copper and aluminum are used for air cooling to implement heat dissipation, the air cooling incorporating the aforesaid copper and aluminum will be unable to satisfy the demand for heat dissipating when the heat release of chips achieves 50 W/cM². Therefore, the high efficiency of heat dissipation materials needs to improve. The structure of a heat dissipation device for electronic components is described as follows.

Referring to FIG. 1, a schematic diagram illustrates a conventional heat dissipation device for electronic components. The conventional heat dissipation device comprises a heat dissipation slip 11, a heat dissipation patch 12, a heat pipe 13, an air stream produce device 14 and a plurality of heat sink fins 15. The heat dissipation slip 11 is made by copper and the heat dissipation patch 12 is stuck on a lower surface 111 of the heat dissipation slip 11. The heat dissipation patch 12 is made by aluminum and is used for adhering an upper surface 161 of a chip 16 and the lower surface 111 of the heat dissipation slip 11 in order to conductive the waste heat generated from the operating of the chip 16. The waste heat is then conducted by the heat dissipation patch 12 to the lower surface 111 of the heat dissipation slip 11. The waste heat is further conducted to a heat source end 131 of the heat pipe 13 from an upper surface 112 of the heat dissipation slip 11. The heat pipe 13 is made by pure copper. A heat dissipation end 132 which is corresponded to the heat source end 131 of the heat pipe 13 is connected to the plurality of heat sink fins 15 and the waste heat is conducted to the plurality of heat sink fins 15. The plurality of heat sink fins 15 is made by copper and is a destination for conducting the waste heat. Lastly, the plurality of heat sink fins 15 are combined with the air stream produce device 14. The air stream produce device 14 is a fan. An air stream is produced by the rotation of the air stream produce device 14 and the air stream is then brought to the plurality of heat sink fins 15 to reduce the high temperature caused by the waste heat, which has been conducted to the plurality of heat sink fins 15. The efficiency of heat dissipation for electronic components can be achieved by using above heat dissipation device.

Besides, diamonds are well known and have characteristics with highest hardness, fastest heat conduction, and widest refraction range in current materials. Diamonds, therefore, are always one of more important materials in engineering due to the excellence characteristics. The thermal conductivity of diamonds at the normal atmospheric temperature is five times more than copper. Moreover, the thermal expansion factor of diamonds at high temperature is very small to show the excellent efficiency for heat dissipating. The feature may help people to differentiate the adulteration of diamonds. In the prior art, many technologies and manufacture procedures have been developed to make diamonds. The direct decomposition for hydrocarbons is the most familiar method like Microwave Plasma Enhance Chemical Vapor Deposition (MPCVD) and Hot Filament CVD (HFCVD). By the aforesaid methods, polycrystalline diamond films can be deposited. The characteristic of the polycrystalline diamond films is same as the single crystal diamonds.

### SUMMARY OF THE INVENTION

Accordingly, to eliminate the waste heat generated by electronic components efficiently and to face the development tendency of electronic components with small volumes and high densities, the object of the present invention is to provide a heat conduction material which is applied in a chip for heat dissipating. The waste heat caused by the high temperature, which is generated from the operation of the chip can be reduced and the heat dissipation efficiency can be also improved. In addition, the heat conduction material provided by the present invention is not only restricted in the heat dissipation of the chip, but also applies to other heat conduction apparatuses.

The heat conduction material provided by the present invention is applied to a heat dissipation device and the heat conduction material comprises combining a metal with a bracket structure of carbon element. The metal can be copper or aluminum or other metals with high thermal conductivity. The bracket structure of carbon element is diamond and can be also used for wrapping the metal surface or for encapsulating in materials. The bracket structure of carbon element can be further used in combination with the metal and the materials. The heat conduction material can be made by chemical vapor deposition, physical vapor deposition, melting or other manufacturing methods.

Other features and advantages of the present invention and variations thereof will become apparent from the following description, drawings, and claims.

### BRIEF DESCRIPTION OF THE DRAWINGS

FIG. 1 is a schematic diagram illustrating a conventional heat dissipation device for electronic components;

FIG. 2 is a schematic diagram illustrating an air blown chip dissipation device according to an embodiment of the present invention;

FIG. 3 is a schematic diagram illustrating the heat pipe according to FIG. 1;

FIG. 4 is a schematic diagram illustrating the plurality of heat sink fins according to an embodiment of the present invention;

FIG. 5 is a schematic diagram illustrating the air stream produce device according to an embodiment of the present invention;

FIG. 6 is a schematic diagram illustrating microwave plasma enhanced chemical vapor deposition for manufacturing a heat dissipation structure according to an embodiment of the present invention; and

FIG. 7 is a schematic diagram illustrates ion beam sputtering for manufacturing a heat dissipation structure according to another embodiment of the present invention.

### DETAILED DESCRIPTION OF THE PREFERRED EMBODIMENTS

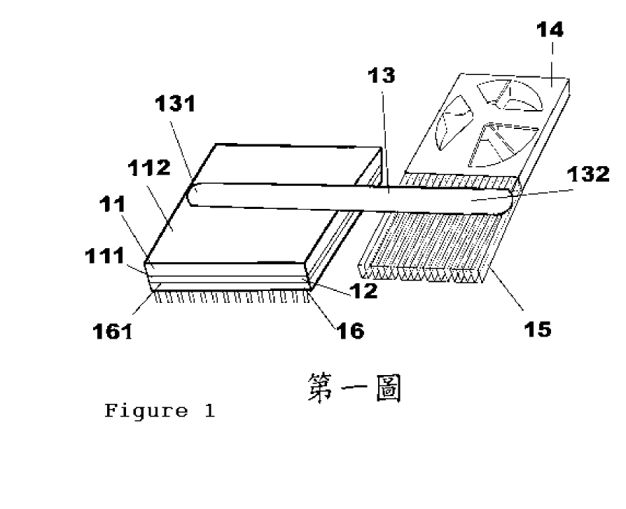

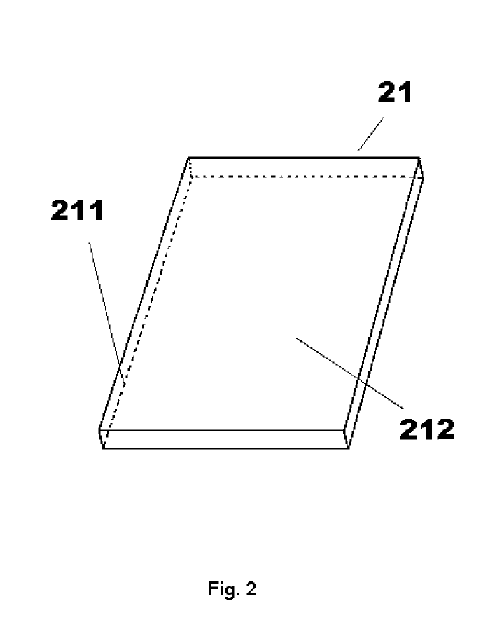

Referring to FIG. 2, a schematic diagram illustrates an air blown chip dissipation device according to an embodiment of the present invention. The operation of the heat dissipation of the device is as same as the prior art. A heat conduction material combining a metal with a bracket structure of carbon element is a material for manufacturing a heat dissipation slip 21. A lower surface 211 of the heat dissipation slip 21 can be bound by the heat dissipation patch 12 to connect the upper surface 161 of the chip 16 as shown in FIG. 1. An upper surface 212 is corresponded to the lower surface 211 of the heat dissipation slip 21. The reaction procedure of heat dissipation for the device is: The lower surface 211 of the heat dissipation slip 21 is through a connection which is corresponded to the upper surface 161 of the chip 16. The waste heat generated by the operation of the chip 16 is conducted to the heat dissipation slip 21 which combines a metal with a bracket structure of carbon element to absorb the waste heat caused by the high temperature, which is generated from the operation of the chip 16. The bracket structure of carbon element is diamonds. The metal can be aluminum alloy or copper or other metals with high thermal conductivity or other metal combinations.

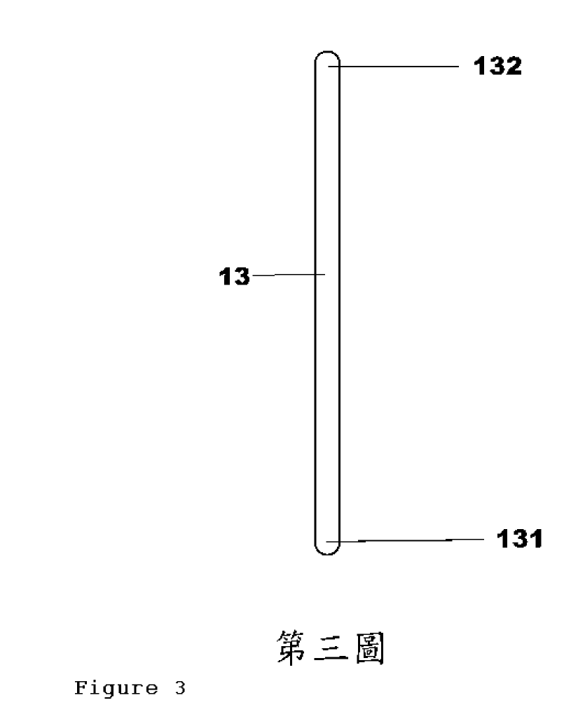

Referring to FIG. 3, a schematic diagram illustrates the heat pipe according to FIG. 1. The heat pipe 13 comprises the heat source end 131 that is connected to the upper surface 212 of the heat dissipation slip 21 which is the heat conduction material combining the metal with the bracket structure of carbon element as shown in FIG. 2. The heat dissipation end 132 which is corresponded to the heat source end 131 is connected to the plurality of heat sink fins 15 as shown in FIG. 1. The waste heat is then conducted to the heat pipe 13 from the heat dissipation slip 21 which combines the metal with the bracket structure of carbon element as shown in FIG. 2.

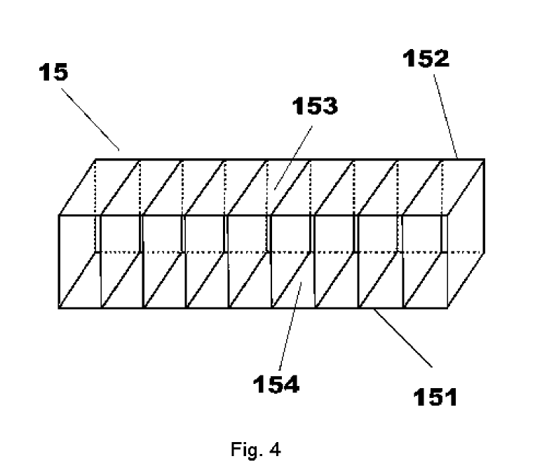

Referring to FIG. 4, a schematic diagram illustrates the plurality of heat sink fins according to an embodiment of the present invention. A bottom 151 is formed by a hemline of the plurality of heat sink fins 15. The bottom 151 is connected to the heat dissipation end 132 of the heat pipe 13 as shown in FIG. 3 to form a connection. There is a top 152 which is corresponded to the bottom 151 to form a top line which is corresponded to the hemline of the plurality of heat sink fins 15. Therefore, an entrance 153 and an exit 154 are composed of the plurality of heat sink fins 15, the bottom 151 and the top 152. An air stream passage is further composed of the entrance 153 and the exit 154 to eliminate the waste heat which has been conducted to the plurality of heat sink fins 15 from the heat pipe 13 as shown in FIG. 3.

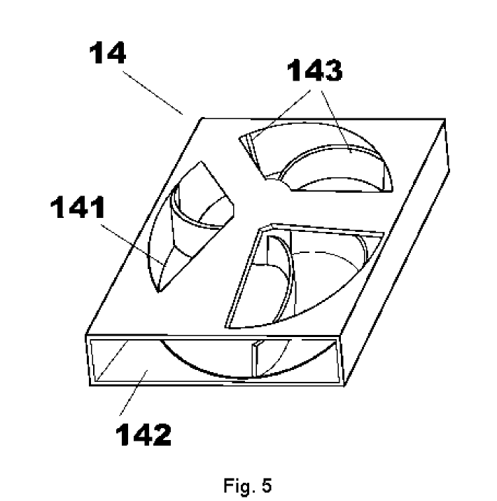

Referring to FIG. 5, a schematic diagram illustrates the air stream produce device according to an embodiment of the present invention. The air stream produce device 14 includes an entrance 141, an exit 142 and a plurality of blades 143. By the rotation of the plurality of blades 143, air is conducted to the exit 142 from the entrance 141 to form an air stream. The air stream produce device 14 is then combined with the plurality of heat sink fins 15 as shown in FIG. 4 to enable the air stream to further enter the entrance 153. The air stream provided by the rotation of the sir stream produce device 14 is then conducted to the entrance 153 of the plurality of heat sink fins 15 from the exit 142 in order to further eliminate the waste heat which has been conducted to the plurality of heat sink fins 15. Lastly, the waste heat is discharged from the exit 154 of the plurality of heat sink fins 15. The heat dissipation can be achieved completely.

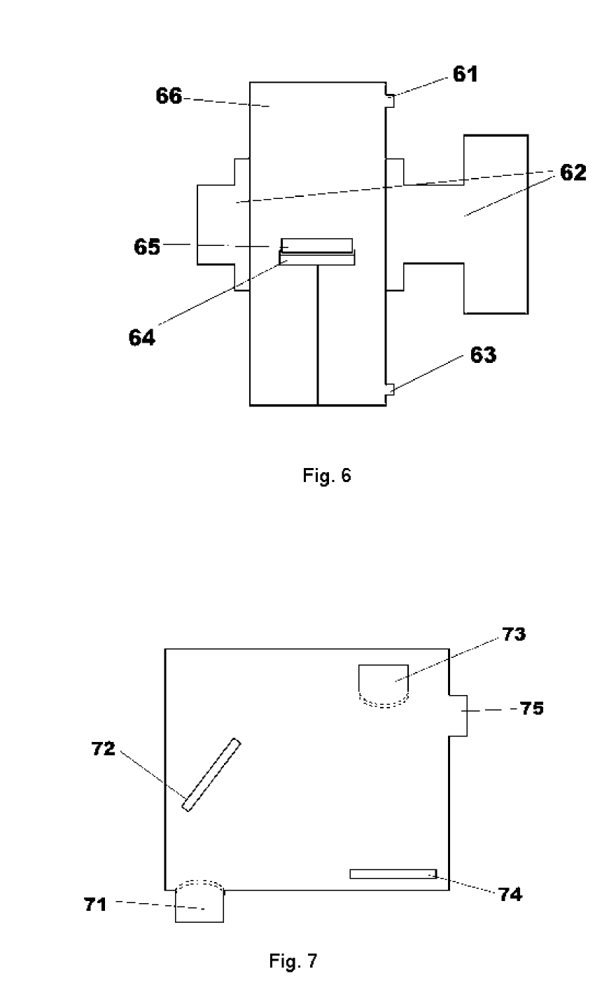

In addition, the heat conduction material having the bracket structure of carbon element can be formed on a metal surface by using CVD or PVD. Referring to FIG. 6, a schematic diagram illustrates microwave plasma enhanced chemical vapor deposition for manufacturing a heat dissipation structure according to an embodiment of the present invention. In the embodiment, the reaction procedure is that a mixed gas for desired reaction is delivered to a gas reaction room 66 from a gas entrance 61. At the same time, a microwave is generated by a microwave generation system 62 to activate the mixed gas in order to provide reactive ions for reacting. A surface of a metal material 65 on a carrier 64 is absorbed to form diamond films. The metal material 65 can be copper or aluminum or other metals with high heat conductivity or other material combinations. Remaining gas is discharged to a waste gas exit 63. By the way mentioned above, a heat conduction material having surface coverage can be acquired that is the heat dissipation slip 21 as shown in FIG. 2.

Referring to FIG. 7, a schematic diagram illustrates ion beam sputtering for manufacturing a heat dissipation structure according to another embodiment of the present invention. In the embodiment, the manufacturing procedure is that a target 72 is molded by diamond materials first of all. The placement angle of the target 72 and the shooting direction of ion beam of a first ion gun 71 are approximately forty five degrees. The diamond particles fired by the first ion gun 71 fly to the front of a second ion gun 73. The diamond particles is then sputtered to the surface of a metal material 74 to form uniform diamond films by providing enough kinetic energy from the first ion gun 71. The remaining diamond particles are discharged by a waste gas exit 75. By the way mentioned above, a heat conduction material having surface coverage can be acquired that is the heat dissipation slip 21 as shown in FIG. 2

Moreover, the heat conduction material having a metal and a bracket structure of carbon element can be further made by electroplating, melting except CVD and PVD of the above embodiments.

Although the features and advantages of the embodiments according to the preferred invention are disclosed, it is not limited to the embodiments described above, but encompasses any and all modifications and changes within the spirit and scope of the following claims.

What is claimed is:

1. An air blown chip heat dissipation device, applied in a chip for heat dissipating, comprising:
an air stream produce device having an exit;
a plurality of heat sink fins having hemline each, formed on a bottom and at least an entrance being formed by the plurality of heat sink fins and the bottom, the entrance being corresponded to the exit;
a heat dissipation slip, set on a plane of the chip and the heat dissipation being combined a metal with a bracket structure of carbon element to form a heat conduction material; and
a heat pipe, set between the plurality of heat sink fins and the heat dissipation slip.

2. The air blown chip heat dissipation device of claim 1, wherein the air stream produce device is a fan.

3. The air blown chip heat dissipation device of claim 1, wherein the plurality of heat sink fins includes a top line which is corresponded to the hemline, the top line is formed under a top which is corresponded to the bottom.

4. The air blown chip heat dissipation device of claim 1, wherein the plane of the chip is a lid of the chip.

5. The air blown chip heat dissipation device of claim 1, wherein the plane of the chip is a bottom surface of the chip.

6. The air blown chip heat dissipation device of claim 1, wherein the metal is copper.

7. The air blown chip heat dissipation device of claim 1, wherein the metal is aluminum.

8. The air blown chip heat dissipation device of claim 1, wherein the metal is silver.

9. The air blown chip heat dissipation device of claim 1, wherein the metal is a metal material with high thermal conductivity coefficient.

10. The air blown chip heat dissipation device of claim 1, wherein the bracket structure of carbon element is a diamond.

11. The air blown chip heat dissipation device of claim 1, wherein the heat conduction material is formed by chemical vapor deposition.

12. The air blown chip heat dissipation device of claim 1, wherein the heat conduction material is formed by physical vapor deposition.

13. The air blown chip heat dissipation device of claim 1, wherein the heat conduction material is formed by electroplating.

14. The air blown chip heat dissipation device of claim 1, wherein the heat conduction material is formed by melting.

15. A manufacturing method for an air blown chip dissipation, applied in a chip for heat dissipating, comprising:
providing an air stream produce device and forming an exit on the air stream produce device;
setting a plurality of heat sink fins on a bottom and at least an entrance being formed by the plurality of heat sink fins and the bottom, the entrance being corresponded to the exit;
using a manufacturing procedure to produce a heat conduction material having a metal and a bracket structure of carbon element;
using the heat conduction material to form a heat dissipation slip;
setting the heat dissipation slip on a plane of the chip; and
setting a heat pipe between the heat dissipation slip and the plurality of heat sink fins.

16. The manufacturing method of claim 15, further comprising providing a fan to be the air stream produce device.

17. The manufacturing method of claim 15, further comprising forming a top which being corresponded to the bottom to enable the plurality of heat sink fins to set between the bottom and the top.

18. The manufacturing method of claim 15, further comprising providing copper to be the metal.

19. The manufacturing method of claim 15, further comprising providing aluminum to be the metal.

20. The manufacturing method of claim 15, further comprising providing silver to be the metal.

21. The manufacturing method of claim 15, further comprising a metal material with high thermal conductivity coefficient to be the metal.

22. The manufacturing method of claim 15, further comprising providing a diamond to be the bracket structure of carbon element.

23. The manufacturing method of claim 15, further comprising providing CVD to form the heat conduction material.

24. The manufacturing method of claim 15, further comprising providing PVD to form the heat conduction material.

25. The manufacturing method of claim 15, further comprising providing electroplating to form the heat conduction material.
